(19) United States
(12) Patent Application Publication
(10) Pub. No.: US 2024/0311268 A1
(43) Pub. Date: Sep. 19, 2024

(54) CONTROL PROGRAM, CONTROL METHOD, AND INFORMATION PROCESSING APPARATUS

(71) Applicant: Renesas Electronics Corporation, Tokyo (JP)

(72) Inventor: Eiichi ARAI, Tokyo (JP)

(21) Appl. No.: 18/439,857

(22) Filed: Feb. 13, 2024

(30) Foreign Application Priority Data
Mar. 17, 2023 (JP) 2023-043222

(51) Int. Cl. G06F 11/34

(52) U.S. Cl. CPC G06F 11/3457; G06F 11/349

(57) ABSTRACT

A control program capable of properly executing high-speed simulation is provided. The control program according to the present disclosure causes an information processing apparatus to execute a control method, the information processing apparatus including a virtual environment for executing a simulation target program. The virtual environment includes a bus master, an interconnect, and a bus slave connected to the bus master via the interconnect. The control method includes an access processing step of causing the bus master to execute the bus access to the bus slave in a different route depending on whether a pointer for executing the bus access from the bus master to the bus slave is held in a pointer holding section, and an operation executing step of causing the bus slave to execute a predetermined operation when being triggered by the bus access from the bus master.

### CROSS-REFERENCE TO RELATED APPLICATION

The disclosure of Japanese Patent Application No. 2023-043222 filed on Mar. 17, 2023, including the specification, drawings and abstract is incorporated herein by reference in its entirety.

### BACKGROUND

The present disclosure relates to a control program, a control method, and an information processing apparatus, and relates to a control program, a control method, and an information processing apparatus capable of, for example, achieving a virtual environment.

There is disclosed technique listed below.
[Patent Document 1] Japanese Unexamined Patent Application Publication No. 2018-200495

A technique in which a virtual environment is used to execute software and to do a simulation is known. As a related art, the Patent Document 1 discloses an information processing apparatus including a virtual environment in which an embedded program for a predetermined embedded device is executed.

In the information processing apparatus disclosed in the Patent Document 1, when bus access for executing “Read” or “Write” on a peripheral intellectual property (IP) register occurs during the simulation of the execution of the embedded program, a virtual central processing unit (CPU) transmits, to a virtual bus section, a transaction that is a Read or Write access command including an address or a size of an access destination. An access processing section in the virtual bus section receives the bus access, and determines whether the access destination of the bus access is present in an access destination list. If the access destination is present in the access list, the access processing section determines whether the access destination is a stub region. If the access destination is the stub region, the access processing section directly accesses the stub region, based on the transaction. If the access destination is not the stub region, the access processing section transmits the transaction to the access destination.

### SUMMARY

Bus topology of System on a Chip (SoC) has been increasingly complicated year by year, and higher-speed simulations for the bus transaction have been emphasized. Typically, in a simulator including bus topology, the bus access for Write, Read or others is executed by sequential calling of bus access application programming interface (API) of a bus interconnect between a bus master and a bus slave (such as b_transport of SystemC or the like). When the API access is executed from the bus master to the bus slave via the interconnect, a simulation speed decreases in proportion to the number of interconnects. The higher-speed simulation is necessary in the information processing apparatus as disclosed in the Patent Document 1.

Other objects and novel characteristics will be apparent from the description of the present specification and the accompanying drawings.

According to one embodiment, a control program according to the present disclosure is a control program causing an information processing apparatus to execute a control method, the information processing apparatus including a virtual environment for executing a simulation target program. The virtual environment includes a bus master, an interconnect, and a bus slave connected to the bus master via the interconnect. The control method includes an access processing step and an operation executing step. In the access processing step, the bus master executes the bus access to the bus slave in a different route depending on whether a pointer for executing the bus access from the bus master to the bus slave is held in a holding section. In the operation executing step, the bus slave executes a predetermined operation when being triggered by the bus access from the bus master. In the access processing step, the bus master executes the bus access directly to the bus slave in accordance with the pointer if the pointer is held, or executes the bus access to the bus slave via the interconnect if the pointer is not held.

According to one embodiment, a control method according to the present disclosure is a control method executed by an information processing apparatus including a virtual environment for executing a simulation target program. The virtual environment includes a bus mater, an interconnect, and a bus slave connected to the bus master via the interconnect. The control method includes an access processing step and an operation executing step. In the access processing step, the bus master executes the bus access to the bus slave in a different route depending on whether a pointer for executing the bus access from the bus master to the bus slave is held in a holding section. In the operation executing step, the bus slave executes a predetermined operation when being triggered by the bus access from the bus master. In the access processing step, the bus mater executes the bus access directly to the bus slave in accordance with the pointer if the pointer is held, or executes the bus access to the bus slave via the interconnect if the pointer is not held.

According to one embodiment, an information processing apparatus according to the present disclosure is an information processing apparatus including a virtual environment for executing a simulation target program. The virtual environment includes a bus mater, an interconnect, and a bus slave connected to the bus master via the interconnect. The bus master includes a holding section and an access processing section. The holding section holds a pointer for executing the bus access from the bus master to the bus slave. The access processing section executes the bass access to the bus slave in a different route depending on whether the pointer is held in the holding section. The bus slave includes an operation executing section for executing a predetermined operation when being triggered by the bus access from the bus master. The access processing section executes the bus access directly to the bus slave in accordance with the pointer if the pointer is held, or executes the bus access to the bus slave via the interconnect if the pointer is not held.

According to the one embodiment, a control program, a control method, and an information processing apparatus capable of appropriately executing high-speed simulation can be provided.

### BRIEF DESCRIPTIONS OF THE DRAWINGS

FIG. 1 is a block diagram illustrating a information processing configuration of an apparatus according to a first embodiment.

FIG. 2 is a diagram schematically illustrating a virtual environment according to the first embodiment.

FIG. 3 is a diagram schematically illustrating a bus access processing according to the first embodiment.

FIG. 4 is a diagram schematically illustrating the bus access processing according to the first embodiment.

FIG. 5 is a flowchart for explaining a flow of the bus access processing according to the first embodiment.

FIG. 6 is a block diagram for explaining a hardware configuration of an information processing apparatus according to a second embodiment.

FIG. 7 is a block diagram for explaining a software configuration according to the second embodiment.

FIG. 8 is a diagram schematically illustrating a flow of data in the software configuration of FIG. 7.

FIG. 9 is a flowchart for explaining a flow of a bus access processing according to the second embodiment.

FIG. 10 is a block diagram for explaining a software configuration according to a third embodiment.

FIG. 11 is a diagram schematically illustrating a flow of data in the software configuration of FIG. 10.

FIG. 12 is a flowchart for explaining a flow of a bus access processing according to the third embodiment.

FIG. 13 is a block diagram for explaining a software configuration according to a fourth embodiment.

FIG. 14 is a diagram schematically illustrating a flow of data in the software configuration of FIG. 13.

FIG. 15 is a flowchart for explaining a flow of a processing of acquiring a routing pointer for executing bus access from a bus master to a guard, according to the fourth embodiment.

FIG. 16 is a flowchart for explaining a flow of a bus access processing according to the fourth embodiment.

FIG. 17 is a diagram illustrating a virtual environment including a plurality of first interconnects according to the fourth embodiment.

### DETAILED DESCRIPTION

In order to solve the above-described issues, it is considerable to employ a method (such as DMI access of SystemC) of causing the bus master to directly read and write a value from and into a pointer of a memory of the bus slave in the bus access for higher-speed simulation. If such a method is employed, the bus master can directly access the bus slave not via the interconnect, and therefore, the higher-speed simulation is achieved.

However, such a method can be used for a bus slave (such as read only memory (ROM) or random access memory (RAM)) configured to execute Read or Write but cannot be used for a bus slave configured to execute a slave operation other than Read or Write in response to the access from the bus master.

For example, it is assumed that the bus slave is a timer. In this case, the bus master executes the bus access to the timer, and requests a storage region of the timer to activate the timer. The timer executes a timer operation in response to the request from the bus master. Thus, the above-described method which can be used for the bus slave configured to execute Read or Write cannot be employed to the bus slave such as the timer configured to execute other operation than Read or Write.

Further, in recent years, a slave operation for functional safety (FuSa) or Security is mounted also on the ROM or the RAM in many cases. The ROM or the RAM not for FuSa or Security is used as the bus slave in less cases. Thus, a range of the employment of the above-described method has been narrowed. In recent years, the use of the above-described method has been difficult to achieve the higher-speed simulation. Therefore, this leads to a decrease in the simulation speed.

For clear explanation, the following description and drawings are appropriately omitted and simplified. Each of elements illustrated in the drawings, respectively, as functional blocks that execute various types of processing can be configured of a CPU, a memory, or another circuit in a hardware manner, or is achieved by execution of a program or the like stored in the memory by the CPU in a software manner. Therefore, it would be understood by those skilled in the art that the functional blocks can be achieved in various forms by only hardware, only software, or their combination, and are not limited to any one of the forms. In the drawings, the same elements are respectively denoted by the same reference symbols, and description thereof is not repeated as needed.

The program may be stored in a non-transitory computer readable medium or a tangible storage medium of various types. The computer readable media or tangible storage media may include, for example, the RAM, the ROM, flash memory, solid-state drive (SSD), other memory techniques, CD-ROM, digital versatile disc (DVD), Blu-ray (registered trademark) disc, other optical disc storages, magnetic cassette, magnetic tape, magnetic disk storage, and other magnetic storage device, but are not limited thereto. The program may be transmitted on a transitory computer readable medium of various types or communication medium. The transitory computer readable media or communication media include, for example, electrical, optical, acoustic, and other-form propagation signals, but are not limited thereto.

### First Embodiment

### (Configuration of Information Processing Apparatus 1000)

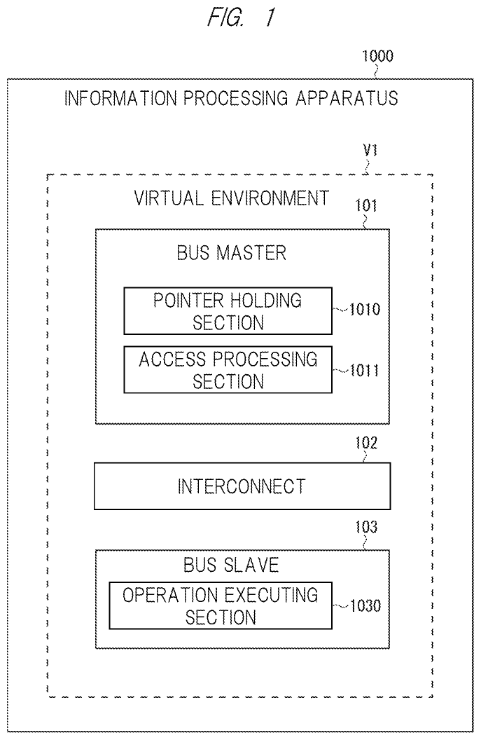

A first embodiment will be first described with reference to FIG. 1. FIG. 1 is a block diagram illustrating a configuration of an information processing apparatus 1000 according to the present embodiment. The information processing apparatus 1000 includes a virtual environment V1 for executing a simulation target program. The information processing apparatus 1000 can achieve the virtual environment V1 on the memory by executing a control program according to the present embodiment.

The virtual environment V1 includes a bus master 101, an interconnect 102, and a bus slave 103 connected to the bus master 101 via the interconnect 102. The bus slave 103 includes an operation executing section 1030 configured to execute a predetermined operation when being triggered by bus access from the bus master 101.

The bus master 101 includes a pointer holding section 1010 and an access processing section 1011. The pointer holding section 1010 holds a pointer for executing bus access from the bus master 101 to the bus slave 103.

The access processing section 1011 executes bus access to the bus slave 103 in a different route depending on whether the pointer is held in the pointer holding section 1010. The access processing section 1011 causes the bus slave 103 to execute a predetermined operation. Then, the access processing section 1011 executes bus access directly to the bus slave 103 in accordance with the pointer if the pointer is held in the pointer holding section 1010, or executes bus access to the bus slave 103 via the interconnect 102 if the pointer is not held.

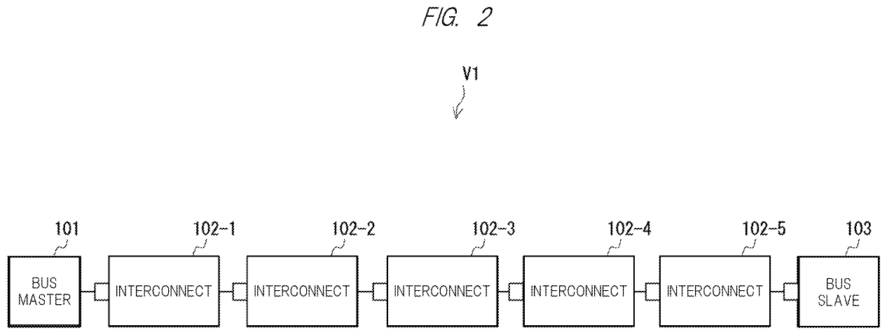

The virtual environment V1 will be described herein with reference to FIG. 2. FIG. 2 is a diagram schematically illustrating the virtual environment V1. The virtual environment V1 includes the bus master 101, the interconnects 102-1, 102-2, . . . , and 102-5, and the bus slave 103 connected to the bus master 101 via the interconnects. The interconnects 102-1, 102-2, . . . , and 102-5 may be simply referred to as interconnects 102 below.

The larger the number of interconnects 102 is, the longer the time taken for the bus access from the bus master 101 to the bus slave 103 is. For example, when a simulation is executed at the time of program development, time taken for the simulation may be long depending on the number or configurations of the interconnects 102, and the simulation may be difficult to be efficiently executed.

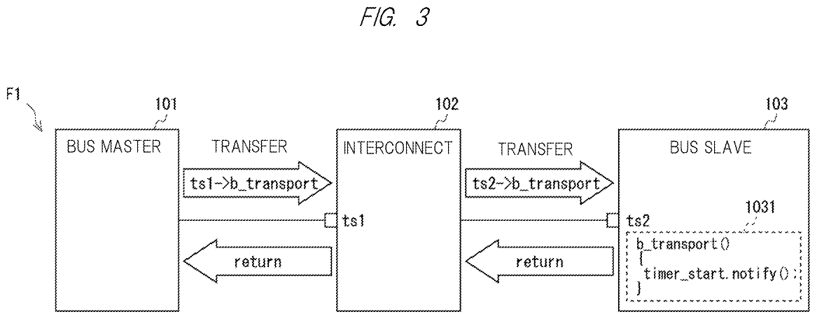

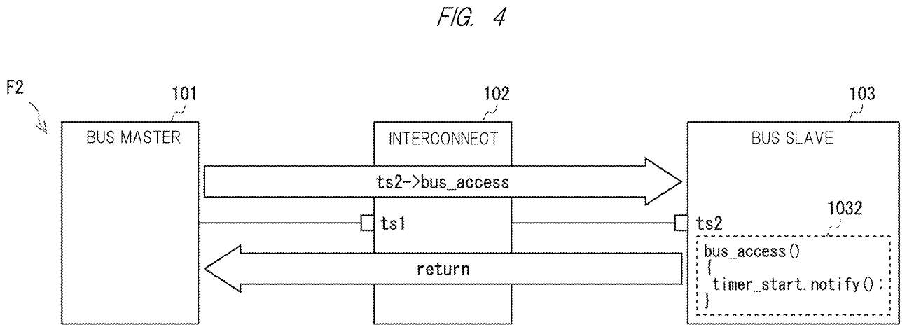

FIGS. 3 and 4 are diagrams each schematically illustrating a bus access processing according to the present embodiment. Note that only one interconnect 102 is illustrated in the drawings. Symbols “ts1” and “ts2” illustrated in the drawings represent pointers used for executing the bus access from the bus master 101 to the bus slave 103.

FIG. 3 illustrates a processing F1 executed when a bus access API of the interconnects 102 between the bus master 101 and the bus slave 103 is sequentially called. FIG. 4 illustrates a processing F2 executed when the bus master 101 executes the bus access directly to the bus slave 103 in accordance with the pointer.

If the pointer is not held in the pointer holding section 1010, the access processing section 1011 in the bus master 101 executes the bus access to the bus slave 103 via the interconnects 102. The operation executing section 1030 in the bus slave 103 executes a predetermined operation when being triggered by the bus access from the access processing section 1011.

If the pointer is held in the pointer holding section 1010, the access processing section 1011 executes the bus access directly to the bus slave 103 in accordance with the pointer. The operation executing section 1030 in the bus slave 103 activates the timer so as to follow, for example, a command indicated in a code 1031 or 1032 when being triggered by the bus access from the bus master 101.

In this manner, if the pointer is held, the access processing section 1011 can execute the high-speed simulation. The bus slave 103 can execute the predetermined operation when being triggered by the bus access from the bus master 101, and therefore, a dedicated bus slave for FuSa or Security can be used for the simulation.

### (Flow of Bus Access Processing)

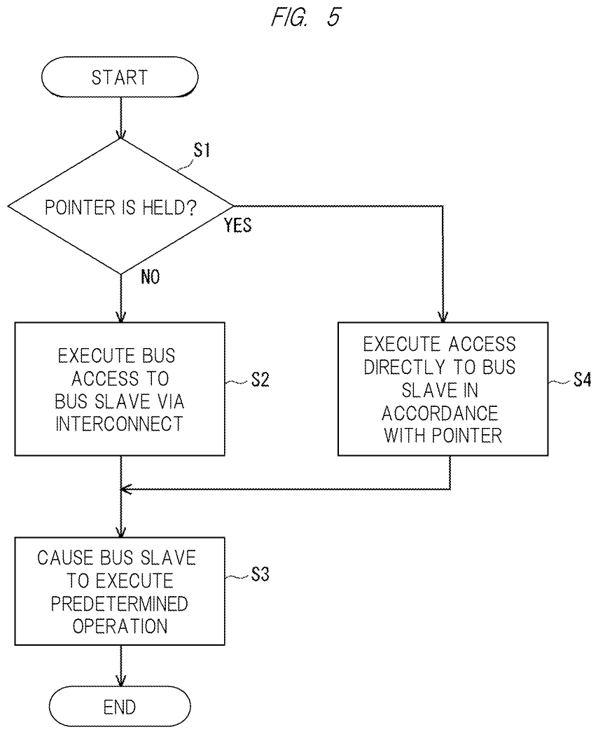

A bus access processing according to the present embodiment will be subsequently described with reference to FIG. 5. FIG. 5 is a flowchart for explaining a flow of the bus access processing according to the present embodiment.

It is first assumed that the bus access from the bus master 101 to the bus slave 103 is executed during the execution of the simulation using the simulation target program. The access processing section 1011 in the bus master 101 refers to the pointer holding section 1010, and determines whether the pointer of a relevant address is held in the pointer holding section 1010 (S1).

If it is determined that the pointer of the relevant address is held (YES in S1), the access processing section 1011 executes the bus access directly to the bus slave 103 by use of the pointer (S4).

If it is determined that the pointer of the relevant address is not held (NO in S1), the access processing section 1011 executes the bus access to the bus slave 103 via the interconnect (S2). The access processing section 1011 causes the bus slave 103 to execute the predetermined operation (S3). The operation executing section 1030 in the bus slave 103 executes the predetermined operation when being triggered by the bus access from the bus master 101.

As described above, in the virtual environment V1 achieved by the information processing apparatus 1000 according to the present embodiment, the access processing section 1011 executes the bus access to the bus slave 103 in a different route depending on whether the pointer is held in the pointer holding section 1010. The access processing section 1011 executes the bus access directly to the bus slave 103 in accordance with the pointer if the pointer is held, or executes the bus access to the bus slave 103 via the interconnect 102 if the pointer is not held. In the manner, the high-speed simulation can be properly executed by the information processing apparatus 1000 according to the present embodiment.

### Second Embodiment

A second embodiment will be subsequently described. The second embodiment is a specific example of the first embodiment.

### (Configuration of Information Processing Apparatus 100)

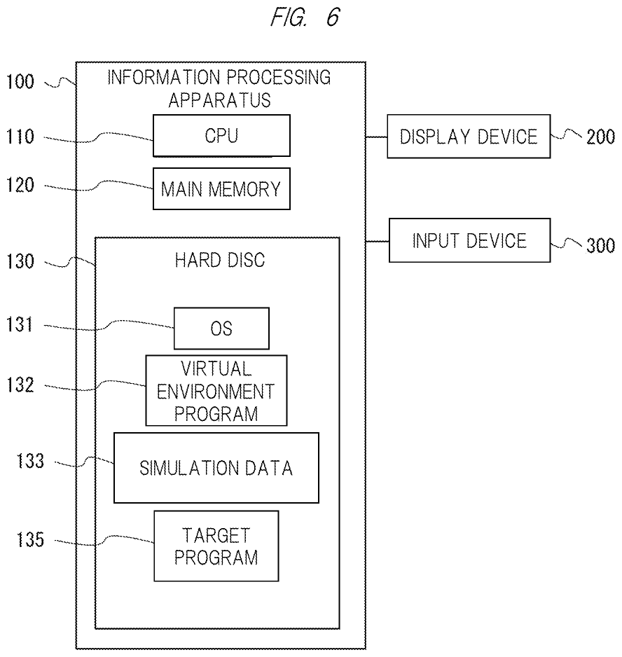

An information processing apparatus 100 according to the present embodiment will be first described with reference to FIG. 6. FIG. 6 is a block diagram for explaining a hardware configuration of the information processing apparatus 100. The information processing apparatus 100 is an example of the information processing apparatus 1000. The information processing apparatus 100 includes the virtual environment for executing the simulation target program.

The information processing apparatus 100 is an example of, for example, a computer system achieving a virtual environment of a microcomputer (not illustrated). The information processing apparatus 100 is connected to a display device 200 and an input device 300.

The display device 200 executes screen display in response to an instruction from the information processing apparatus 100. The input device 300 inputs a user instruction to the information processing apparatus 100. The input device 300 is, for example, a keyboard receiving input of character information from a user, a mouse designating any position the screen of the display device 200 and receiving input of an instruction depending on an icon or the like displayed at the position, or the like. However, devices to be connected to the information processing apparatus 100 are not limited thereto.

The information processing apparatus 100 includes a CPU 110, a main memory 120, and a hard disc 130. The CPU 110 is a control device reading and executing a predetermined program. The main memory 120 is a volatile storage device such as RAM. The hard disc 130 is a non-volatile storage device. The hard disc 130 stores therein an operating system (OS) 131, a virtual environment program (control program) 132, simulation data 133, a target program 135, and the like.

The OS 131 is fundamental software for operating the information processing apparatus 100. The virtual environment program 132 is, for example, software for achieving the microcomputer as the embedded device in software form to simulate the execution of the target program 135 on this microcomputer. The virtual environment program 132 causes the information processing apparatus including the virtual environment for executing the simulation target program to execute the control method. The virtual environment includes the bus master, the interconnect, the bus slave connected to the bus master via the interconnect. The control method includes the access processing step of causing the bus master to execute the bus access to the bus slave in the different route depending on whether the pointer for executing the bus access from the bus master to the bus slave is held in the holding section. The control method further includes the operation executing step of causing the bus slave to execute the predetermined operation when being triggered by the bus access from the bus master. In the access processing step, if the pointer is held, the bus master executes the bus access directly to the bus slave in accordance with the pointer. Alternatively, in the access processing step, if the pointer is not held, the bus master executes the bus access to the bus slave via the interconnect.

The simulation data 133 is various types of data used for the simulation. The simulation data 133 may include, for example, a program achieving various functions of a simulator, and information of a simulation target device. The target program 135 is the simulation target program. The target program 135 may be, for example, software developed to be executed on a predetermined embedded device. The target program 135 is executed for debug or the like by the virtual environment program 132.

The CPU 110 described here loads the OS 131, the virtual environment program 132, the simulation data 133, and the target program 135, which are stored in the hard disc 130, onto the main memory 120. The CPU 110 then executes the os 131 and the virtual environment program 132 having been loaded on the main memory 120. The CPU 110 executes the target program 135 by executing the virtual environment program 132. Thus, the information processing apparatus 100 can be regarded as including the virtual environment for executing the target program 135.

### (Software Configuration)

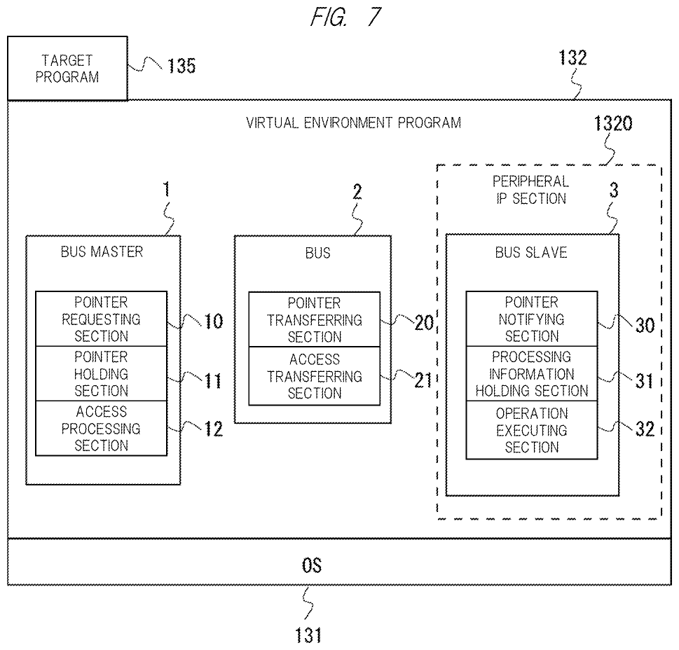

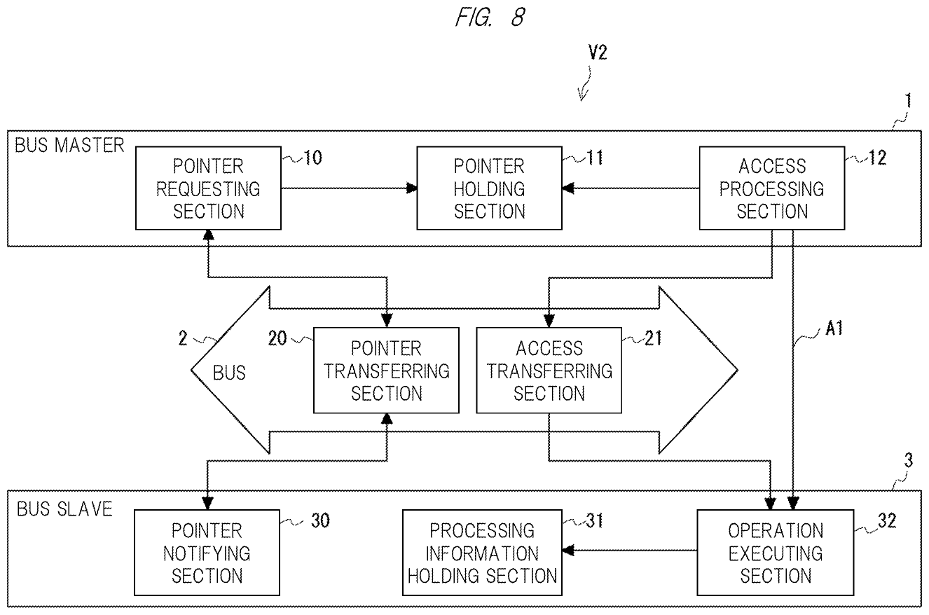

A software configuration according to the present embodiment will be subsequently described with reference to FIGS. 7 and 8. FIG. 7 is a block diagram for explaining the software configuration according to the present embodiment. FIG. 8 is a diagram schematically illustrating a flow of data in the software configuration of FIG. 7. Note that a one-way arrow in FIG. 8 briefly indicates a flow of information (data, signal or the like), and does not intend to eliminate bidirectionality of the information. This point is also applicable to the subsequent figures. Although only a bus 2 is illustrated as an example of the interconnect in FIG. 8, the number and type of interconnects are not limited thereto.

FIG. 7 illustrates that the virtual environment program 132 operates on the OS 131 while the target program 135 operates on the virtual environment program 132.

The virtual environment program 132 is an example of a program for achieving a virtual environment V2 according to the present embodiment. As illustrated in the drawings, the virtual environment V2 includes the bus master 1, the bus 2, and a peripheral IP section 1320. The bus master 1, the bus 2, and the peripheral IP section 1320 are virtually achieved on the main memory 120 by executing the virtual environment program 132. The bus master 1, the bus 2, and the peripheral IP section 1320 are defined as, for example, classes, and are achieved when being instantiated at the time of the execution of the virtual environment program 132.

As illustrated in FIG. 8, the virtual environment V2 includes the bus master 1 and a bus slave 3 connected to the bus master 1 via the bus 2. Description will be made herein while using the bus 2 as an example of the interconnect.

The bus master 1 is an example of the bus master 101. The bus master 1 includes a pointer requesting section 10, a pointer holding section 11, and an access processing section 12. The bus master 1 is, for example, a CPU, a direct memory access (DMA) controller, or the like, but is not limited thereto.

The pointer requesting section 10 functions as a pointer acquiring section configured to acquire the pointer via the bus 2. The pointer requesting section 10 acquires the pointer from the bus slave 3 via the bus 2 if the pointer is not held in the pointer holding section 11. Specifically, to the bus slave 3, the pointer requesting section 10 outputs a pointer request for requesting a notification of the pointer. The pointer requesting section 10 causes the pointer holding section 11 to hold the acquired pointer.

The pointer holding section 11 is an example of the pointer holding section 1010. The pointer holding section 11 holds the pointer for executing the bus access from the bus master 1 to the bus slave 3.

The access processing section 12 is an example of the access processing section 1011. The access processing section 12 executes the bus access to the bus slave 3 in the different route depending on whether the pointer is held in the pointer holding section 11. The access processing section 12 causes the bus slave 3 to execute the predetermined operation.

The access processing section 12 executes the bus access directly to the bus slave 3 in accordance with the pointer if the pointer is held in the pointer holding section 11. In FIG. 8, a flow of the bus access is indicated by an arrow A1. If the pointer is not held in the pointer holding section 11, the access processing section 12 executes the bus access to the bus slave 3 via the bus 2. Specifically, the access processing section 12 outputs a request of the access to the bus slave 3, to an access transferring section 21, and executes the access request to the bus slave 3 via the access transferring section 21.

The bus 2 is an example of the interconnect. The bus 2 includes a pointer transferring section 20 and the access transferring section 21.

The pointer transferring section 20 transfers data regarding the pointer between the bus master 1 and the bus slave 3. For example, to the bus slave 3, the pointer transferring section 20 transfers a pointer request received from the bus master 1. To the pointer requesting section 10, the pointer transferring section 20 transfers the pointer notified from the bus slave 3.

The access transferring section 21 transfers data regarding the bus access between the bus master 1 and the bus slave 3. For example, to the bus slave 3, the access transferring section 21 transfers an access request received from the bus master 1.

The peripheral IP section 1320 includes the bus slave 3. The bus slave 3 is an example of the bus slave 103. The bus slave 3 has a function of executing the predetermined operation when being triggered by the bus access from the bus master 1. The bus slave 3 may have a function corresponding to, for example, a register. In this case, the bus slave 3 is configured such that a register which is originally hardware is achieved on software. The bus slave is not limited to the register, and other IP may be used as the bus slave 3.

The bus slave 3 includes a pointer notifying section 30, a processing information holding section 31, and an operation executing section 32. The pointer notifying section 30 notifies the bus master 1 of the pointer via the bus 2 in response to the pointer request output from the bus master 1.

The processing information holding section 31 holds processing information related to the processings of the operation executing section 32. For example, the processing information holding section 31 may simply have the Read or Write function as described above. For example, when writing is executed from the access processing section 12 into the operation executing section 32, the processing information holding section 31 holds a write value. The processing information can be used in response to a request from the bus master 1. For example, the access processing section 12 in the bus master 1 acquires the processing information held in the processing information holding section 31, and determines whether the predetermined operation has been executed in the operation executing section 32.

The operation executing section 32 is an example of the operation executing section 1030. The operation executing section 32 executes the predetermined operation when being triggered by the bus access from the bus master 1. The operation executing section 32 has a function corresponding to, for example, API.

The predetermined operation represents an operation to be executed by the operation executing section 32 when being triggered by the bus access from the bus master 1. The operation executing section 32 executes the predetermined operation when receiving the bus access directly from the bus master 1 and when receiving the bus access s from the bus master 1 via the bus 2. The predetermined operation is, for example, activation of a timer, A/D conversion, or the like, but is not limited thereto.

For example, a Read or Write processing in a memory or the like having only the Read or Write function, to which the above-described method is applicable, is not included in the predetermined operation triggered by the bus access from the bus master 1. For example, in the above-described processing information example, the operation executing section 32 reads the processing information held in the processing information holding section 31 in response to a request from the access processing section 12, and returns it to the operation executing section 32. However, the simple Read operation or the like is not included in the predetermined operations triggered by the bus access from the bus master 1.

### (Flow of Bus Access Processing)

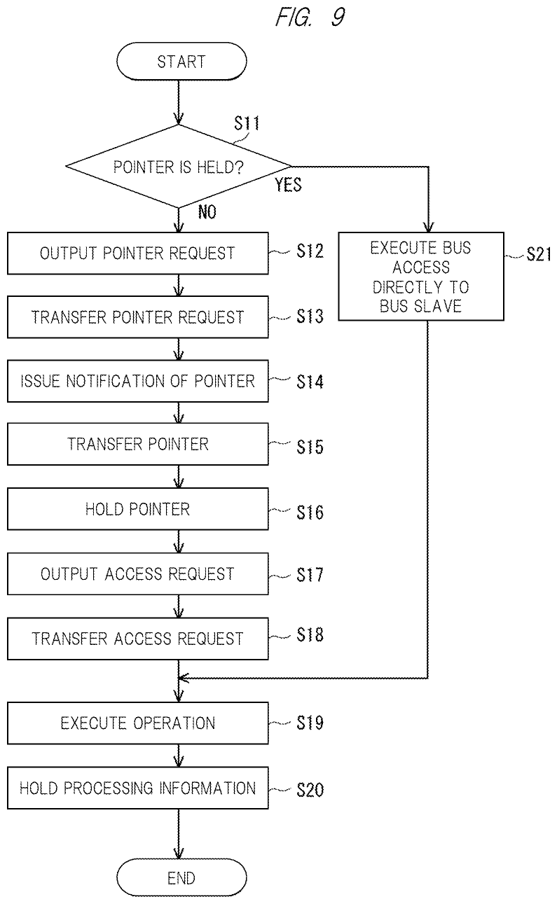

A bus access processing according to the present embodiment will be subsequently described with reference to FIG. 9. FIG. 9 is a flowchart for explaining a flow of the bus access processing according to the present embodiment.

First, it is assumed that the bus access is executed from the bus master 1 to the bus slave 3 during the execution of the simulation of the target program 135. The access processing section 12 in the bus master 1 refers to the pointer holding section 11, and determines whether the pointer of the relevant address is held (S11). The pointer is information for calling API corresponding to the operation executing section 32 in the bus slave 3.

If it is determined that the pointer of the relevant address is held (YES in S11), the access processing section 12 executes the bus access directly to the operation executing section 32 in the bus slave 3 by use of the pointer (S21). In the manner, the operation executing section 32 executes the operation (S19). The operation executing section 32 reads data from or writes data into the processing information holding section 31, and causes the processing information holding section 31 to hold the processing information (S20). The processing information is, for example, a write value corresponding to the operation of the operation executing section 32. The processing information holding section 31 holds the processing information in a memory region.

If it is determined that the pointer of the relevant address is not held in step S11 (NO in S11), the pointer requesting section 10 in the bus master 1 outputs a pointer request to the bus slave 3 (S12). In the manner, the pointer requesting section 10 requests the bus slave 3 to issue notification of the pointer.

The pointer transferring section 20 in the bus 2 transfers the pointer request (S13). The pointer notifying section 30 in the bus slave 3 issues the notification of the pointer in response to the pointer request (S14). The pointer transferring section 20 transfers the notified pointer to the pointer requesting section 10 (S15). In the manner, the pointer requesting section 10 can acquire the pointer from the bus slave 3 via the bus 2.

The pointer requesting section 10 causes the pointer holding section 11 to hold the acquired pointer (S16). In the manner, at the time of next bus access, the access processing section 12 can execute the bus access directly to the operation executing section 32 while referring to the pointer holding section 11.

The access processing section 12 executes the bus access to the bus slave 3 via the bus 2 (S17). To the access transferring section 21, the access processing section 12 outputs a request of the access to the bus slave 3. In the manner, the access processing section 12 requests the bus access to the bus slave 3. The access transferring section 21 transfers the access request (S18).

The operation executing section 32 receives the access request, and executes the operation (S19). The operation executing section 32 causes the processing information holding section 31 to hold a value related to the execution of the operation (S20).

The above-described processing order is exemplified. The processing order may be changed as needed. For example, in the above-described explanation, in the case of NO in step S11, the pointer is requested and held in steps S12 to S16 while the bus access to the bus slave 3 and the holding of the value are executed in steps S17 to S20. However, the processings in steps S17 to S20 may be executed earlier, and then, the processings in steps S12 to S16 may be executed later.

As described above, in the processings executed by the virtual environment program 132 according to the present embodiment, the bus slave 3 in the virtual environment V2 includes the operation executing section 32 configured to execute the predetermined operation in response to the bus access from the bus master 1. The bus master 1 includes the pointer holding section 11 configured to hold the pointer for executing the bus access to the bus slave 3 and the access processing section 12 configured to execute the bus access to the bus slave 3 in the different route depending on whether the pointer is held in the pointer holding section 11.

The access processing section 12 executes the bus access directly to the bus slave 3 in accordance with the pointer if the pointer is held in the pointer holding section 11, or executes the bus access to the bus slave 3 via the bus 2 if the pointer is not held. The pointer requesting section 10 acquires the pointer from the bus slave 3 via the bus 2 if the pointer is not held.

In the manner, at the time of first bus access after the start of the simulation, the bus master 1 acquires the pointer for calling API corresponding to the operation executing section 32 while executing the bus access to the bus slave 3 via the bus 2. In the manner, at next and subsequent bus accesses, the bus master 1 can directly call API of the operation executing section 32 to execute the bus access while using the pointer.

In the manner, even if there are a plurality of interconnects, the bus accesses at the time of second and subsequent bus accesses can be executed without losing the slave operation during one API calling time irrespective of the number of interconnects. In the manner, the information processing apparatus 100 according to the present embodiment can properly achieve the high-speed bus access simulation without losing the slave operation while keeping the bus configuration similar to that in hardware.

### Third Embodiment

A third embodiment will be subsequently described. The third embodiment is a modification example of the second embodiment. In the virtual environment V2 according to the second embodiment, the bus access at the time of first simulation is executed via the bus 2 that is the interconnect, and the bus accesses at the time of second and subsequent simulations are executed not via the bus 2 but directly. In a virtual environment V3 according to the present embodiment, it can be selected whether to route via the interconnect at the time of second and subsequent simulations.

Differences from the second embodiment will be mainly described below, and the overlapping points with the second embodiment will be omitted as needed. A configuration of an information processing apparatus 100a according to the present embodiment is almost similar to that of the information processing apparatus 100 according to the second embodiment (see FIG. 6), and therefore, will not be illustrated. The hard disc 130 in the information processing apparatus 100a includes a virtual environment program 132a instead of the virtual environment program 132. The information processing apparatus 100a executes the virtual environment program 132a to achieve the virtual environment V3.

### (Software Configuration)

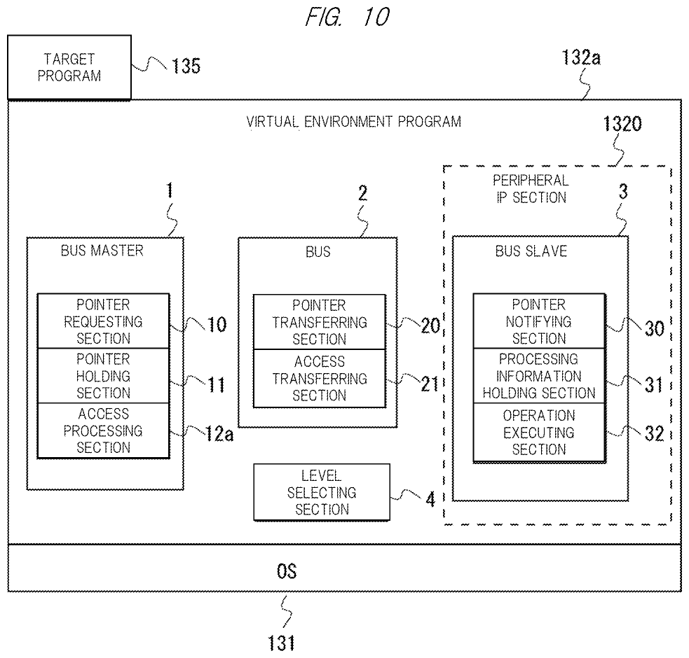

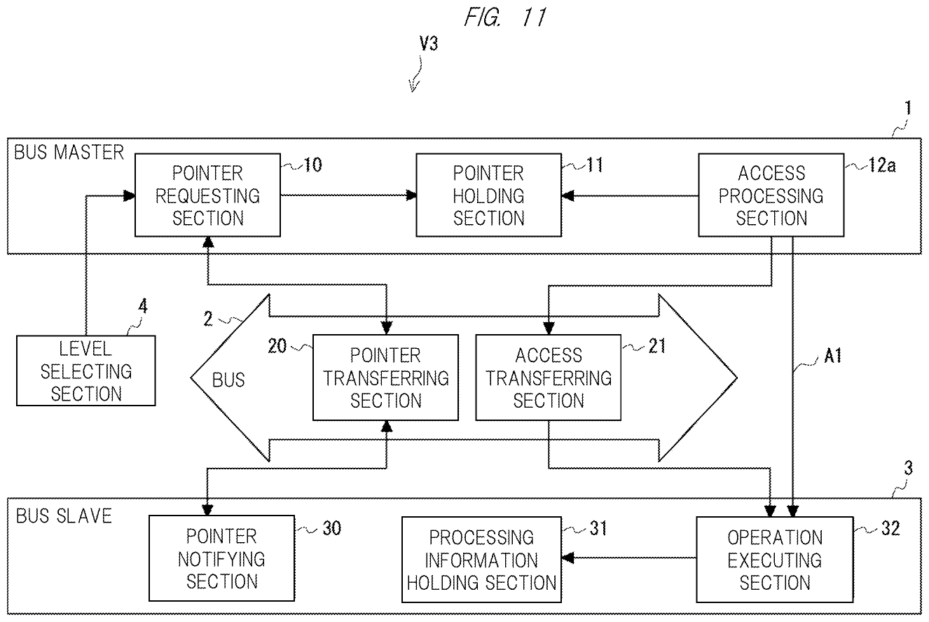

With reference to FIGS. 10 and 11, a software configuration according to the present embodiment will be described. FIG. 10 is a block diagram for explaining the software configuration according to the present embodiment. FIG. 11 is a diagram schematically illustrating a flow of data in the software configuration of FIG. 10.

As illustrated in FIG. 10, the virtual environment program 132a according to the present embodiment includes a level selecting section 4 in addition to the virtual environment program 132 according to the second embodiment (see FIG. 7). The level selecting section 4 is connected to the pointer requesting section 10. The level selecting section 4 selects the simulation level from among a simulation plurality of levels with different simulation speeds.

The simulation level is information indicating that priority of the simulation is put on either speed or accuracy. The simulation level is indicated as, for example, two steps such as “high speed” putting the priority on speed and “high accuracy” putting the priority on accuracy. The simulation levels in two steps correspond to the routes of the bus access from the bus master 1 to the bus slave 3, respectively.

The level selecting section 4 selects the simulation level in response to, for example, user input via the input device 300. Alternatively, the level selecting section 4 switches the simulation level in response to user input. The level selecting section 4 outputs the selected simulation level to the pointer requesting section 10 in the bus master 1. The pointer requesting section 10 stores the selected simulation level in a storage section (not illustrated). An access processing section 12a in the bus master 1 acquires the selected simulation level from the storage section.

The access processing section 12a executes the bus access to the bus slave 3 in the route corresponding to the level selected in the level selecting section 4. The access processing section 12a executes the bus access directly to the bus slave 3 if the speed-priority simulation level is selected in the level selecting section 4. Alternatively, the access processing section 12a executes the bus access to the bus slave 3 via the bus 2 if the simulation level other than the speed-priority simulation level is selected therein. The simulation level other than the speed-priority simulation level is, for example, the accuracy-priority simulation level.

It is assumed that the simulation level is, for example, “high speed.” The access processing section 12a executes the bus access directly from the bus master 1 to the bus slave 3 without via the bus 2. In FIG. 11, the route of the direct access to the bus slave 3 is indicated by an arrow A1.

For example, it is assumed that the simulation level is “high accuracy.” The access processing section 12a executes the bus access to the bus slave 3 via the bus 2. In this case, the access processing section 12a executes the bus access to the bus slave 3 via the access transferring section 12 in the bus 2 as similar to the access processing section 21 according to the second embodiment.

As described above, the access processing section 12a selects a different route depending on the selected simulation level, and executes the bus access to the bus slave 3 in the route. In the manner, the information processing apparatus 100a can execute the speed- or accuracy-priority simulation.

Note that the examples of FIGS. 10 and 11 show, for example, one bus master 1 and one bus slave 3. However, under an actual environment, a plurality of bus masters may execute the bus access to one bus slave. In such a case, a low-priority bus master waits until the bus access from a high-priority bus master ends in order to avoid collision between the bus accesses. Thus, a waiting time occurs until the waiting state is eliminated.

In such a case, although a program execution result can be simulated, time taken for executing the program cannot be correctly simulated. For example, even if the program execution result is confirmed as correct, the time for the execution may not meet a performance goal. Thus, in such a case, the user preferably executes the accuracy-priority simulation.

### (Flow of Bus Access Processing)

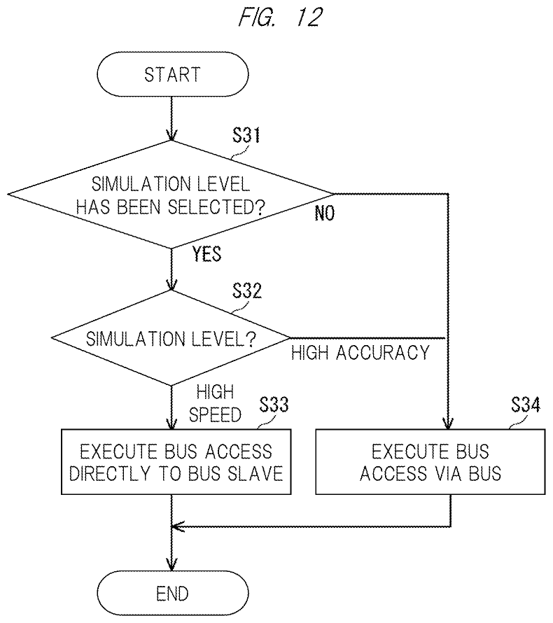

A bus access processing according to the present embodiment will be subsequently described with reference to FIG. 12. FIG. 12 is a flowchart for explaining a flow of the bus access processing according to the present embodiment. Note that a processing needed for acquiring the pointer at the time of first simulation and others is similar to that of the second embodiment described with reference to FIG. 9. Description will be made herein in assumption of the second and subsequent simulations.

First, the level selecting section 4 determines whether the simulation level has been selected (S31). If it is determined that the simulation level has been selected (YES in S31), the level selecting section 4 determines whether the selected simulation level is “high speed” or “high accuracy” (S32). If it is determined that the simulation level is “high speed” (“high speed” in S32), the access processing section 12a executes the bus access directly to the bus slave 3 without via the bus 2 (S33).

If it is determined that the simulation level is “high accuracy” (“high accuracy” in S32) or that the simulation level has not been selected (NO in S31), the access processing section 12a executes the bus access to the bus slave 3 via the bus 2 (S34).

Note that the second and subsequent simulations are assumed herein. However, the level selecting section 4 may select “high speed” at the time of first simulation. In this case, when the processing of acquiring the pointer can be executed as similar to the second embodiment, the access processing section 12a can execute the bus access directly to the bus slave 3 even at the time of first simulation.

As described above, in the processing executed by the virtual environment program 132a according to the present embodiment, the level selecting section 4 selects the simulation level in the virtual environment V3. The access processing section 12a in the bus master 1 accesses the bus slave 3 in a route corresponding to the selected simulation level.

As described above, because of the addition of the level selecting section 4, both speed-priority and accuracy-priority simulations can be achieved by the configuration without newly creating a simulator. In particular, there are many demands for dynamic switching using Python I/F or the like between the speed-priority and accuracy-priority simulations. Specifically, for example, during a less-important simulation period such as Linux (trademark) boot, the simulation is executed while putting the priority on the speed, and can be switched to the accuracy-priority simulation after reaching a point to which the user is paid attention. In the manner, efficient simulation can be executed.

### Fourth Embodiment

A fourth embodiment will be subsequently described. The fourth embodiment is a modification example of the third embodiment. The virtual environment V3 according to the third embodiment enables the bus access using the corresponding two-step routes in accordance with the selected simulation level. In the third embodiment, a simulation method needs to be selected from among methods that are the speed-priority simulation excluding all the interconnects or the accuracy-priority simulation including all the interconnects and are completely opposite to each other.

Simulation needs for FuSa or Security have increased in recent years. The present embodiment enables the high-speed simulation for the bus access including any IP by providing a simulation target IP with a pointer notifying section, a pointer requesting section, and a pointer holding section.

Differences from the second and third embodiments will be mainly described below, and the overlapping points with them will be omitted as needed. A configuration of an information processing apparatus 100b according to the present embodiment is almost similar to that of the information processing apparatus 100 according to the second embodiment (see FIG. 6), and therefore, will not be illustrated. The hard disc 130 in the information processing apparatus 100b includes a virtual environment program 132b instead of the virtual environment program 132. The information processing apparatus 100b achieves a virtual environment V4 by executing the virtual environment program 132b. The virtual environment V4 includes a plurality of interconnects.

### (Software Configuration)

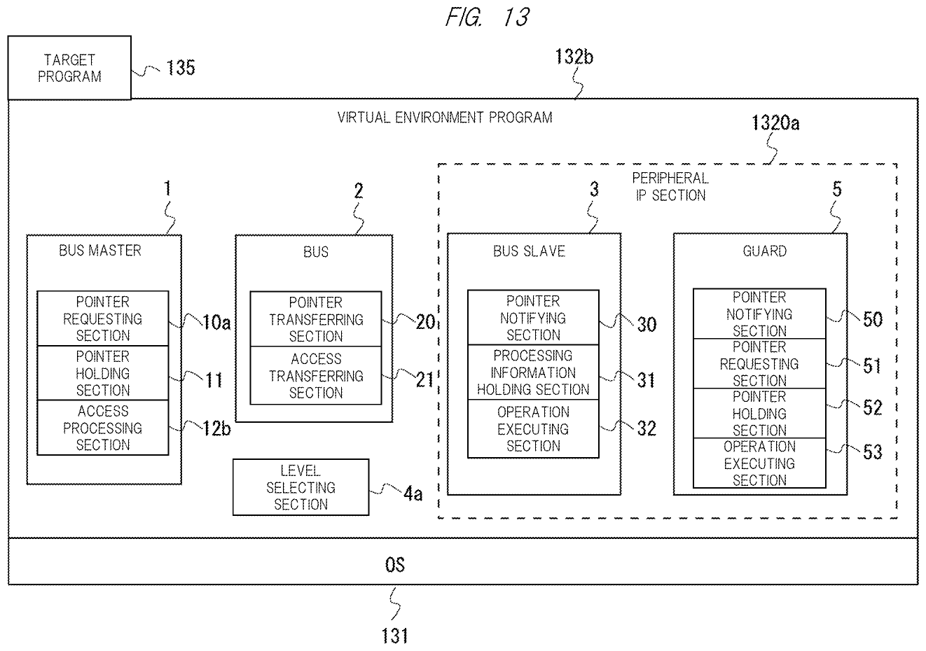

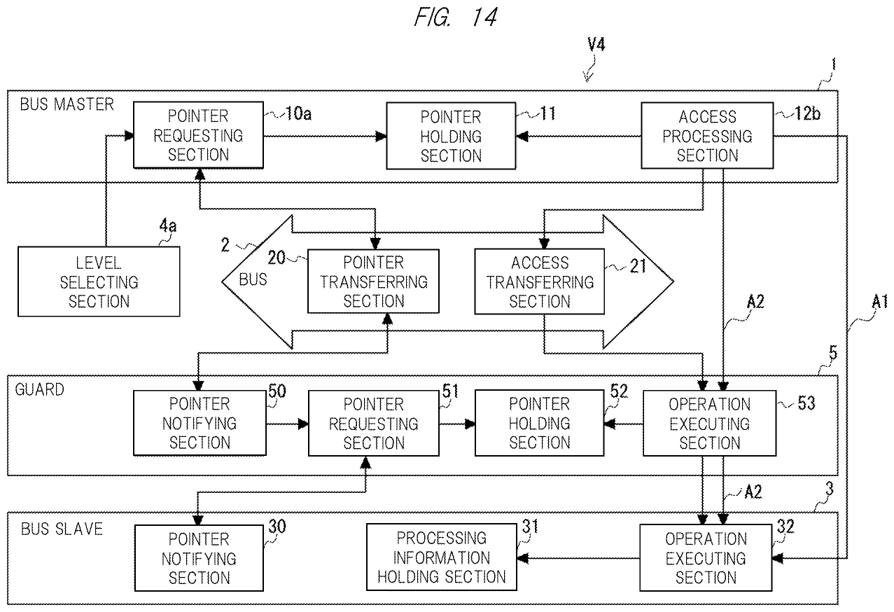

A software configuration according to the present embodiment will be described with reference to FIGS. 13 and 14. FIG. 13 is a block diagram for explaining the software configuration according to the present embodiment. FIG. 14 is a diagram schematically illustrating a flow of data in the software configuration of FIG. 13.

As illustrated in FIG. 14, the virtual environment V4 includes a plurality of interconnects including a first interconnect to be routed in the bus access from the bus master 1 to the bus slave 3 and a second interconnect not to be routed. The first interconnect is a route target interconnect in the bus access while the second interconnect is not the route target interconnect in the bus access. In the bus access from the bus master 1 to the bus slave 3, data output from the bus master 1 reaches the bus slave 3 via the first interconnect. In this bus access, the data output from the bus master 1 reaches the bus slave 3 without via the second interconnect. Description will be made herein in assumption that the first interconnect is a guard 5 while the second interconnect is the bus 2.

As illustrated in FIG. 13, the virtual environment program 132b according to the present embodiment includes a peripheral IP section 1320a corresponding to the peripheral IP section 1320 of the virtual environment program 132a according to the third embodiment (see FIG. 10). The peripheral IP section 1320a includes the guard 5 in addition to the bus slave 3. The guard 5 is an example of the interconnect having a function of limiting the bus access from the bus master 1 to the bus slave 3.

The guard 5 includes a pointer notifying section 50, a pointer requesting section 51, a pointer holding section 52, and an operation executing section 53. The pointer notifying section 50 issues notification of a routing pointer in response to a routing pointer request from a pointer requesting section 10a. The routing pointer is information for calling API corresponding to the operation executing section 53 in the guard 5.

The pointer requesting section 51 outputs a pointer request to the pointer notifying section 30 in the bus slave 3. In the manner, the pointer requesting section 51 requests the bus slave 3 the notification of the pointer. The pointer requesting section 51 causes the pointer holding section 52 to hold the pointer acquired from the pointer notifying section 30.

The pointer holding section 52 holds the pointer acquired in the pointer requesting section 51. The operation executing section 53 accesses the operation executing section 32 in the bus slave 3. In the manner, the operation executing section 53 executes the simulation without losing the slave operation for the necessary IP.

A level selecting section 4a can select not only the speed-priority and accuracy-priority simulation levels but also a predetermined simulation level other than these simulation levels. As the predetermined simulation level, the level selecting section 4a further selects a simulation level for functional safety. For example, the level selecting section 4a is configured to select a simulation level for FuSa in addition to “high speed.” The simulation level “FuSa” is a functional safety-priority simulation level. For example, the simulation is executed by the bus access via more interconnects in the selection of the simulation level “FuSa” than the selection of the simulation level “high speed”. Thus, in this case, the simulation putting the priority on not the speed but the functional safety can be executed. And, the simulation is executed by the bus access via less interconnects in the selection of the simulation level “FuSa” than the selection of the simulation level “high accuracy”. Thus, this case can achieve the higher-speed simulation than that of the case of the simulation level “high accuracy”. In the present embodiment, three-step simulation levels that are “high speed,” “high accuracy,” and “FuSa” can be set. More-step simulation levels can be set depending on selection of the interconnects to be routed.

If the routing pointer is not held in the pointer holding section 11, the pointer requesting section 10a in the bus master 1 also functions as the routing pointer acquiring section configured to acquire the routing pointer from the guard 5. If it is determined that the routing pointer of the relevant address is not held, a routing pointer request is output to the guard 5. In the manner, the pointer requesting section 10a requests the guard 5 the notification of the routing pointer. The pointer requesting section 10a causes the pointer holding section 11 to hold the routing pointer acquired from the guard 5.

An access processing section 12b executes the bus access to the bus slave 3 in a different route depending on whether the routing pointer for executing the bus access from the bus master 1 to the guard 5 is held in the pointer holding section 11. The access processing section 12b acquires the simulation level output from the level selecting section 4a via the pointer requesting section 10a and the storage section not illustrated.

If the pointer and the routing pointer are held in the pointer holding section 11, the access processing section 12b executes the bus access to the bus slave 3 in a route corresponding to the simulation level selected by the level selecting section 4a. For example, if the routing pointer is held while the simulation level is “FuSa,” the access processing section 12b executes the bus access directly to the operation executing section 53. The operation executing section 53 executes the bus access to the operation executing section 32. In the manner, the access processing section 12b executes the bus access to the bus slave 3 via only the guard 5 without via the bus 2. The route of the bus access is indicated by an arrow A2 in FIG. 14.

If the speed-priority simulation level “high speed” is selected in the level selecting section 4a, the access processing section 12b executes the bus access directly to the bus slave 3. The route of the bus access is indicated by an arrow A1 in FIG. 14.

The pointer holding section 11 in the bus master 1 further holds the routing pointer for executing the bus access from the bus master 1 to the guard 5. The level selecting section 4a further selects the simulation level for functional safety. If the pointer and the routing pointer are held in the pointer holding section 11, the access processing section 12b executes the bus access to the bus slave 3 in the route corresponding to the selected simulation level.

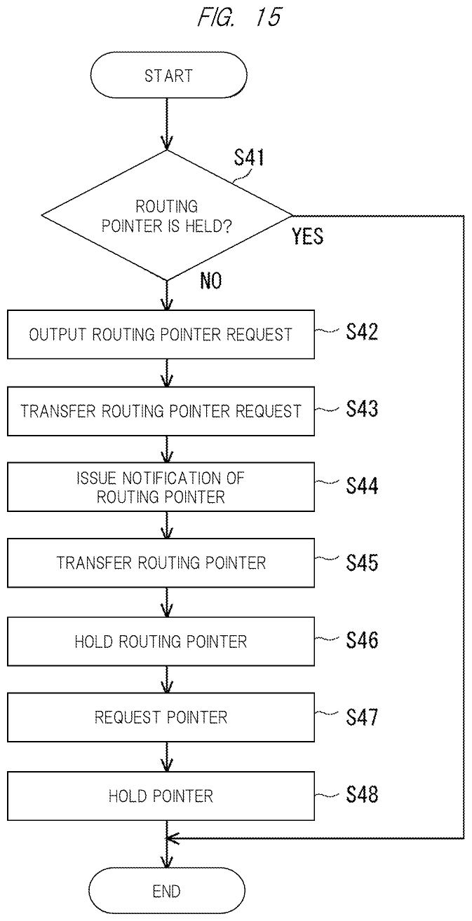

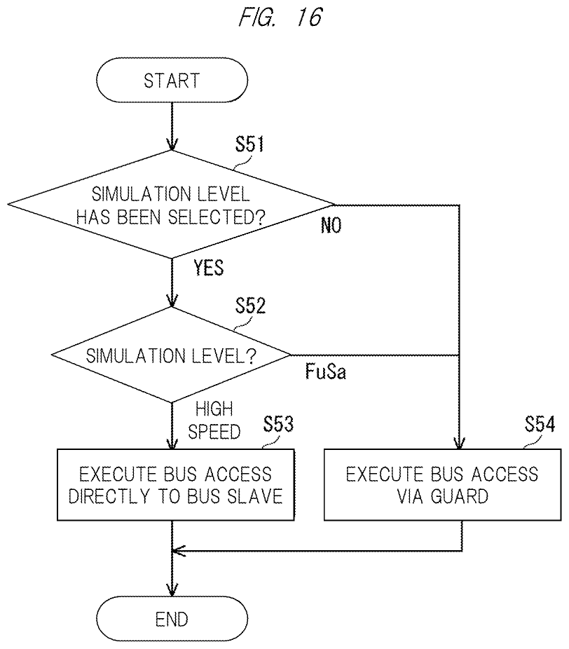

A bus access processing according to the present embodiment will be subsequently described with reference to FIGS. 15 and 16. FIG. 15 is a flowchart for explaining a flow of a processing of acquiring the routing pointer for executing the bus access from the bus master 1 to the guard 5 according to the present embodiment. FIG. 16 is a flowchart for explaining a flow of the bus access processing according to the present embodiment. Note that a processing of acquiring the pointer for executing the bus access directly from the bus master 1 to the bus slave 3 is similar to that of the second embodiment described with reference to FIG. 9.

### (Flow of Processing of Acquiring Routing Pointer)

First, a flow of the processing of acquiring the routing pointer will be described with reference to FIG. 15. The processing of acquiring the routing pointer for executing the bus access from the bus master 1 to the guard 5 will be described herein.

First, it is assumed that the bus access is executed from the bus master 1 to the bus slave 3 during the execution of the simulation of the target program 135. The access processing section 12b in the bus master 1 refers to the pointer holding section 11, and determines whether the routing pointer for executing the bus access from the bus master 1 to the guard 5 is held (S41). The routing is information for pointer calling API corresponding to the operation executing section 53 in the guard 5.

If it is determined that the routing pointer of the relevant address is held (YES in S41), the processing ends. If it is determined that the routing pointer of the relevant address is not held (NO in S41), the pointer requesting section 10a in the bus master 1 outputs a routing pointer request to the guard 5 (S42). In the manner, the pointer requesting section 10a requests the guard 5 the notification of the routing pointer.

The pointer transferring section 20 in the bus 2 transfers the routing pointer request (S43). The pointer notifying section 50 in the guard 5 issues notification of the routing pointer in response to the routing pointer request (S44). The pointer transferring section 20 transfers the notified routing pointer to the pointer requesting section 10a (S45). In the manner, the pointer requesting section 10a can acquire the routing pointer from the guard 5 via the bus 2.

The pointer requesting section 10a causes the pointer holding section 11 to hold the acquired routing pointer (S46). In the manner, the access processing section 12b can execute the bus access directly to the operation executing section 53 with reference to the pointer holding section 11.

Subsequently, the pointer requesting section 51 in the guard 5 outputs a pointer request to the pointer notifying section 30 in the bus slave 3 (S47). In the manner, the pointer requesting section 51 requests the bus slave 3 the notification of the pointer. The pointer requesting section 51 causes the pointer holding section 52 to hold the pointer acquired from the pointer notifying section 30 (S48). Note that the above-described order of the processings is an example, and may be changed as needed.

### (Flow of Bus Access Processing)

A flow of the bus access processing according to the present embodiment will be subsequently described with reference to FIG. 16. First, the level selecting section 4a determines whether the simulation level has been selected (S51). If it is determined that the simulation level has been selected (YES in S51), the level selecting section 4a determines whether the selected simulation level is “high speed” or “FuSa” (S52). If it is determined that the simulation level is “high speed” (“high speed” in S52), the access processing section 12b executes the bus access directly to the bus slave 3 without via the bus 2 (S53).

If it is determined that the simulation level is “FuSa” (“FuSa” in S52) or that the simulation level has not been selected (NO in S51), the access processing section 12b executes the bus access to the bus slave 3 via the guard 5 by executing the bus access to the operation executing section 53 in the guard 5 (S54). The access processing section 12b does not take a route via the bus 2 arranged between the bus master 1 and the guard 5. The operation executing section 53 can execute the simulation without losing the slave operation for the necessary IP by accessing the operation executing section 32.

As described above, in the processings executed by the virtual environment program 132b according to the present embodiment, the virtual environment V4 includes the first interconnect that is the route target and the second interconnect that is not the route target. The user can select whether the interconnect is to be the route target. In the virtual environment V4, the level selecting section 4a selects the simulation level for functional safety. The access processing section 12b in the bus master 1 accesses the bus slave 3 in the route corresponding to the selected simulation level.

In the manner, the simulation target IP can be selected, and the high-speed simulation for FuSa can be executed without the interconnect other than, for example, the guard 5. In the present embodiment, various simulations can be executed by the configuration without newly creating a simulator. In the manner, various simulations such as the speed-priority simulation excluding all the interconnects arranged between the bus master and the bus slave, the accuracy-priority simulation including all the interconnects, and the simulation including the necessary IP can be handled.

Specifically, a Guard model is essential for a simulation for guarding unauthorized access by Guard IP. However, Arbiter, bus bridge, and other interconnects are unnecessary. In this case, only the Guard model is to be simulated in addition to the bus master and the bus slave. To the contrary, if a bus traffic is simulated, only an interconnect such as Arbiter influencing a bus timing is to be simulated, and IP such as Guard is excluded.

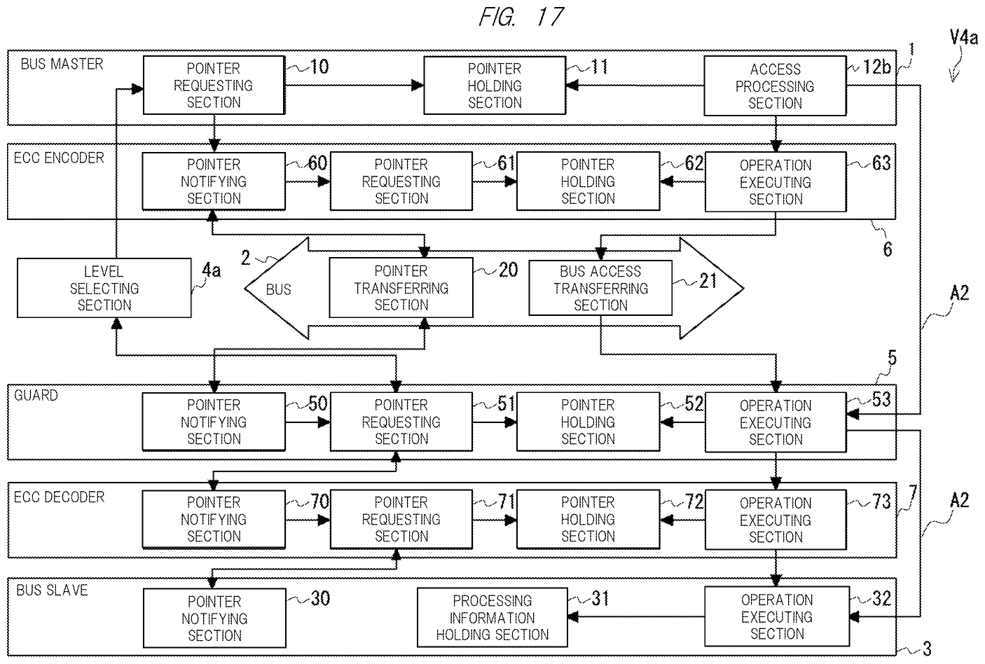

Note that the virtual environment V4 may include a plurality of first interconnects. FIG. 17 is a diagram illustrating a virtual environment 4a including the plurality of first interconnects. As the first interconnects, the virtual environment 4a further includes an error correction code (ECC) encoder 6 and an ECC decoder 7, which achieve an ECC function, in addition to the guard 5.

The ECC is an example of IP for error correction. The ECC encoder 6 and the ECC decoder 7 configure the ECC function for the bus 2. Bus access data is output from the bus master 1, and then, is added with encoded data for detecting bit inversion of data output in the ECC encoder 6, is decoded immediately before reaching the bus slave 3, and is corrected as needed after the detection of the bit inversion. Typically, the ECC is not the simulation target. However, in a case of examination of ECC correction algorithm or the like, the ECC encoder 6 and the ECC decoder 7 can be set to be the route targets.

The ECC encoder 6 includes a pointer notifying section 60, a pointer requesting section 61, a pointer holding section 62, and an operation executing section 63. The ECC decoder 7 includes a pointer notifying section 70, a pointer requesting section 71, a pointer holding section 72, and an operation executing section 73. The functions of the ECC encoder 6 and the ECC decoder 7 correspond to the pointer notifying section 50, the pointer requesting section 51, the pointer holding section 52, and the operation executing section 53 of the guard 5, respectively, and thus, detailed description thereof will be omitted.

The access processing section 12b acquires the simulation level output from the level selecting section 4a via the pointer requesting section 10 and the storage section not illustrated. The access processing section 12b accesses the guard 5 in the route (A2) corresponding to the acquired simulation level. The operation executing section 53 acquires the simulation level output from the level selecting section 4a via the pointer requesting section 51 and the storage section not illustrated. The operation executing section 53 accesses the bus slave 3 in the route (A2) corresponding to the acquired simulation level.

The plurality of first interconnects may be arranged at any positions between the bus master 1 and the bus slave 3. For example, at least one of the plurality of interconnects may be arranged between the bus first master 1 and the second interconnect and between the second interconnect and the bus slave 3, respectively. In the example of FIG. 17, the ECC encoder 6 is arranged between the bus master 1 and the bus 2. The guard 5 and the ECC decoder 7 are arranged between the bus 2 and the bus slave 3. According to the present embodiment, efficient simulation can be executed irrespective of the arrangements of the plurality of first interconnects and the second interconnect.

The information processing apparatuses according to the first to fourth embodiments have been described above. Note that the configurations of the information processing apparatuses 1000, 100, 100a, and 100b are only exemplified, and may be changed as needed. For example, when part or all of the components of such an information processing apparatus is achieved by a plurality of information processing apparatuses, circuits, or the like, the plurality of information processing apparatuses, circuits, or the like may be collectively arranged or distributed. For example, the information processing apparatuses, circuits, or the like may be configured so that client-server system, Cloud computing system or the like is connected via a communication network. Alternatively, the function of such an information processing apparatus according to the embodiments may be provided in a software as a service (Saas) form.

In the foregoing, the invention made by the inventors of the present application has been concretely described on the basis of the embodiments. However, it is needless to say that the present invention is not limited to the foregoing embodiments, and various modifications and alterations can be made within the scope of the present invention. And, the above-described embodiments can be achieved in any combination. For example, part or all of the first to fourth embodiments can be achieved in combination.

What is claimed is:

1. A control program of causing an information processing apparatus to execute a control method, the information processing apparatus including a virtual environment for executing a simulation target program, the virtual environment including a bus master, an interconnect, and a bus slave coupled to the bus master via the interconnect, the control method comprising:
an access processing step of causing the bus master to execute bus access to the bus slave in a different route depending on whether a pointer for executing the bus access from the bus master to the bus slave is held in a holding section; and
an operation executing step of causing the bus slave to execute a predetermined operation when being triggered by the bus access from the bus master, and
wherein in the access processing step, the bus master is configured to:
execute the bus access directly to the bus slave in accordance with the pointer if the pointer is held; and
execute the bus access to the bus slave via the interconnect if the pointer is not held.

2. The control program according to claim 1,
wherein the control method further includes:
a pointer acquiring step of causing the bus mater to acquire the pointer from the bus slave via the interconnect if the pointer is not held in the holding section; and
a pointer holding step of causing the bus master to cause the holding section to hold the acquired pointer.

3. The control program according to claim 1,
wherein the control method further includes a level selecting step of selecting a simulation level from among a plurality of simulation levels with different simulation speeds, and
wherein in the access processing step, the bus master is configured to execute the bus access to the bus slave in a route corresponding to the selected simulation level.

4. The control program according to claim 3,
wherein in the access processing step, the bus master is configured to:
execute the bus access directly to the bus slave if a speed-priority simulation level is selected in the level selecting step; and
execute the bus access to the bus slave via the interconnect if a simulation level other than the speed-priority simulation level is selected.

5. The control program according to claim 3,
wherein the virtual environment includes a plurality of interconnects including a first interconnect to be routed in the bus access from the bus master to the bus slave and a second interconnect not to be routed,
wherein in the access processing step, the bus master is configured to execute the bus access to the bus slave in a different route depending on whether a routing pointer for executing the bus access from the bus master to the first interconnect is held in the holding section, and
wherein in the access processing step, the bus master is configured to execute the bus access to the bus slave in a route corresponding to the selected simulation level if the pointer and the routing pointer are held.

6. The control program according to claim 5,
wherein the control method further includes:
a routing pointer acquiring step of causing the bus mater to acquire the routing pointer from the first interconnect if the routing pointer is not held in the holding section; and
a routing pointer holding step of causing the bus mater to cause the holding section to hold the acquired routing pointer.

7. The control program according to claim 5,
wherein in the access processing step, the bus master is configured to:
execute the bus access directly to the bus slave if a speed-priority simulation level is selected in the level selecting step; and
execute the bus access to the bus slave in a route via the first interconnect but not via the second interconnect if a predetermined simulation level other than the speed-priority simulation level is selected.

8. The control program according to claim 5,
wherein, as the first interconnect, the virtual environment includes an intellectual property (IP) section having a function to limit the bus access from the bus master to the bus slave.

9. The control program according to claim 5,
wherein the virtual environment includes a plurality of the first interconnects, and
at least one of the plurality of first interconnects is arranged between the bus master and the second interconnect and between the second interconnect and the bus slave, respectively.

10. A control method executed by an information processing apparatus including a virtual environment for executing a simulation target program, the virtual environment including a bus mater, an interconnect, and a bus slave coupled to the bus master via the interconnect, the control method comprising:
an access processing step of causing the bus master to execute the bus access to the bus slave in a different route depending on whether a pointer for executing the bus access from the bus master to the bus slave is held in a holding section; and
an operation executing step of causing the bus slave to execute a predetermined operation when being triggered by the bus access from the bus master, and
wherein in the access processing step, the bus mater is configured to:
execute the bus access directly to the bus slave in accordance with the pointer if the pointer is held; and
execute the bus access to the bus slave via the interconnect if the pointer is not held.

11. The control method according to claim 10, further comprising:
a pointer acquiring step of causing the bus master to acquire the pointer from the bus slave via the interconnect if the pointer is not held in the holding section; and
a pointer holding step of causing the bus master to cause the holing section to hold the acquired pointer.

12. An information processing apparatus comprising a virtual environment for executing a simulation target program,
wherein the virtual environment includes:
a bus master;
an interconnect; and
a bus slave coupled to the bus master via the interconnect,
wherein the bus master includes:
a holding section configured to hold a pointer for executing the bus access from the bus master to the bus slave; and
an access processing section configured to execute the bus access to the bus slave in a different route depending on whether the pointer is held in the holding section,
wherein the bus slave includes an operation executing section configured to execute a predetermined operation when being triggered by the bus access from the bus master, and
wherein the access processing section is configured to:
execute the bus access directly to the bus slave in accordance with the pointer if the pointer is held; and
execute the bus access to the bus slave via the interconnect if the pointer is not held.

13. The information processing apparatus according to claim 12,
wherein the bus master further includes a pointer acquiring section configured to acquire the pointer,
wherein the pointer acquiring section is configured to acquire the pointer from the bus slave via the interconnect if the pointer is not held, and
wherein the holding section is configured to hold the acquired pointer.
